(19) United States
(12) Patent Application Publication
(10) Pub. No.: US 2026/0026210 A1
(43) Pub. Date: Jan. 22, 2026

(54) DISPLAY DEVICE, ELECTRONIC DEVICE, AND MANUFACTURING METHOD OF THE DISPLAY DEVICE

(71) Applicant: Samsung Display Co., LTD., Yongin-si (KR)

(72) Inventors: SEUNG JUN YU, Yongin-si (KR); SHIN TACK KANG, Yongin-si (KR); CHANG OK KIM, Yongin-si (KR); HYUN-SEOK KIM, Yongin-si (KR); SOOHYUN PARK, Yongin-si (KR)

(21) Appl. No.: 19/225,103

(22) Filed: Jun. 2, 2025

(30) Foreign Application Priority Data
Jul. 17, 2024 (KR) 10-2024-0094702
Dec. 24, 2024 (KR) 10-2024-0195296

(51) Int. Cl. H10K 59/124; G02B 27/01; H10D 62/10; H10D 86/01; H10D 86/40; H10K 59/12

(52) U.S. Cl. CPC H10K 59/124; H10D 62/124; H10D 86/0221; H10D 86/431; H10K 59/1201; G02B 27/0172

(57) ABSTRACT

Disclosed is a display device which includes a base layer, a first metal layer disposed on the base layer and disposed in a first area, an inorganic layer disposed on the base layer and disposed in a second area, and a second metal layer disposed on the first metal layer and the inorganic layer. A depression portion adjacent to the first metal layer and formed in a thickness direction of the inorganic layer is defined in the inorganic layer.

This application claims priority to Korean Patent Application No. 10-2024-0094702, filed on Jul. 17, 2024, and Korean Patent Application No. 10-2024-0195296, filed on Dec. 24, 2024, and all the benefits accruing therefrom under 35 U.S.C. § 119, the contents of which in their entirety are herein incorporated by reference.

### BACKGROUND

### Field

Embodiments of the present disclosure described herein relate to a display device, an electronic device, and method of manufacturing a display device, and more particularly, relate to a display device, an electronic device, and method of manufacturing a display device having improved reliability.

### Description of the Related Art

A display device, such as, for example, a television, a monitor, a smart phone, a tablet computer, or the like, which provides an image to a user includes a display panel that displays an image. Various display panels, such as, for example, a liquid crystal display panel, an organic light emitting display panel, an electro wetting display panel, an electrophoretic display panel, and the like, are being developed.

Light emitting elements and drive elements of the display panel may be formed by stacking thin films and subjecting the thin films to patterning using masks. The process of manufacturing the display panel using the masks may be costly, and therefore it is desired to reduce the number of masks used in the manufacture of the display device by simplifying the display panel manufacturing process. In some cases, it may be desired to manufacture the display panel to have relatively high reliability while simplifying the process.

### SUMMARY

Embodiments of the present disclosure provide a display device and an electronic device which have relatively high reliability and are capable of providing high resolution images.

According to an embodiment, a display device includes a base layer, a first metal layer disposed on the base layer and disposed in a first area, an inorganic layer disposed on the base layer and disposed in a second area, and a second metal layer disposed on the first metal layer and the inorganic layer. A depression portion adjacent to the first metal layer and formed in a thickness direction of the inorganic layer is defined in the inorganic layer.

According to an embodiment, an electronic device includes a camera module and a display device that displays an image corresponding to a captured image obtained through the camera module. The display device includes a base layer, a first metal layer disposed on the base layer and disposed in a first area, an inorganic layer disposed on the base layer and disposed in a second area, and a second metal layer disposed on the first metal layer and the inorganic layer. A depression portion adjacent to the first metal layer and formed in a thickness direction of the inorganic layer is defined in the inorganic layer.

According to an embodiment, a method for manufacturing a display device includes a step of forming a base layer including a first area and a second area which does not overlap the first area, a step of forming, on the base layer, a first metal layer which overlaps the first area, a step of forming a preliminary inorganic layer on the base layer and the first metal layer, a step of forming an inorganic layer which overlaps the second area, by etching the preliminary inorganic layer, and a step of forming a second metal layer on the first metal layer and the inorganic layer.

A depression portion adjacent to the first metal layer and formed in a thickness direction of the inorganic layer is defined in the inorganic layer.

### BRIEF DESCRIPTION OF THE DRAWINGS

The above and other objects and features of the present disclosure will become apparent by describing in detail embodiments thereof with reference to the accompanying drawings.

FIG. 1 is a perspective view of a display device according to an embodiment of the present disclosure.

FIG. 2 is a sectional view of the display device illustrated in FIG. 1.

FIG. 3 is a sectional view of a display panel illustrated in FIG. 2.

FIG. 4 is a plan view of the display panel illustrated in FIG. 2.

FIG. 5 is a view illustrating a display device according to an embodiment of the present disclosure.

FIG. 6 is an exploded perspective view of the display device illustrated in FIG. 5.

FIG. 7 is a view illustrating an equivalent circuit of one of pixels illustrated in FIG. 4.

FIG. 8 is a timing chart of signals for operating the pixel illustrated in FIG. 7.

FIG. 9 is a schematic sectional view of the pixel illustrated in FIG. 7.

FIG. 10 is an enlarged view of area AA′ illustrated in FIG. 9.

FIGS. 11 and 12 are enlarged views illustrating a portion of a cross-section of the display panel according to an embodiment of the present disclosure.

FIGS. 13A to 13G are process views illustrating a portion of a manufacturing process of the display device according to an embodiment of the present disclosure.

FIGS. 14A to 14D are process views illustrating a portion of a manufacturing process of the display device according to an embodiment of the present disclosure.

FIGS. 15A to 15D are process views illustrating a portion of a manufacturing process of the display device according to an embodiment of the present disclosure.

FIG. 16 is a block diagram of an electronic device including the display device according to an embodiment of the present disclosure.

### DETAILED DESCRIPTION

In this specification, when a component (or, an area, a layer, a part, or the like) is referred to as being “on”, “connected to” or “coupled to” another component, this means that the component may be directly on, connected to, or coupled to the other component or a third component may be present therebetween.

Identical reference numerals refer to identical components. In the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms as used herein may distinguish one component, part, area, layer, or portion from other components, parts, areas, layers, or portions. For example, without departing the scope and scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. The terms of a singular form may include plural forms unless otherwise specified.

Terms such as “below”, “under”, “above”, and “over” are used to

describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

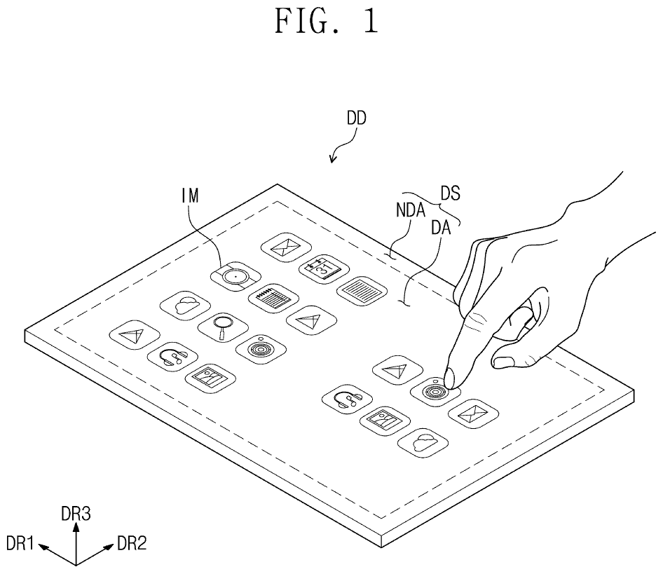

FIG. 1 is a perspective view of a display device according to an embodiment of the present disclosure.

Referring to FIG. 1, the display device DD according to an embodiment of the present disclosure may have a rectangular shape with long sides extending in a first direction DR1 and short sides extending in a second direction DR2 crossing the first direction DR1. However, without being limited thereto, the display device DD may have various shapes such as, for example, a circular shape, a polygonal shape, and the like.

Hereinafter, a direction substantially perpendicular to a plane defined by the first direction DR1 and the second direction DR2 is defined as a third direction DR3. The expression “when viewed from above the plane” used herein may mean that it is viewed in the third direction DR3.

The upper surface of the display device DD may be defined as a display surface DS and may have a plane defined by the first direction DR1 and the second direction DR2. Images IM generated by the display device DD may be provided to a user through the display surface DS.

The display surface DS may include a display area DA and a non-display area NDA around the display area DA. The display area DA may display an image, and the non-display area NDA may not display an image. The non-display area NDA may define the border of the display device DD that surrounds the display area DA and that is printed in a certain color.

The display device DD may be used in large electronic devices such as, for example, a television, a monitor, and a billboard. In some aspects, the display device DD may be used in small and medium-sized electronic devices such as, for example, a personal computer, a notebook computer, a personal digital terminal, a car navigation device, a game machine, a smart phone, a tablet computer, and a camera. However, these electronic devices are illustrative, and the display device DD may be used in other electronic devices without departing from the spirit and scope of the present disclosure.

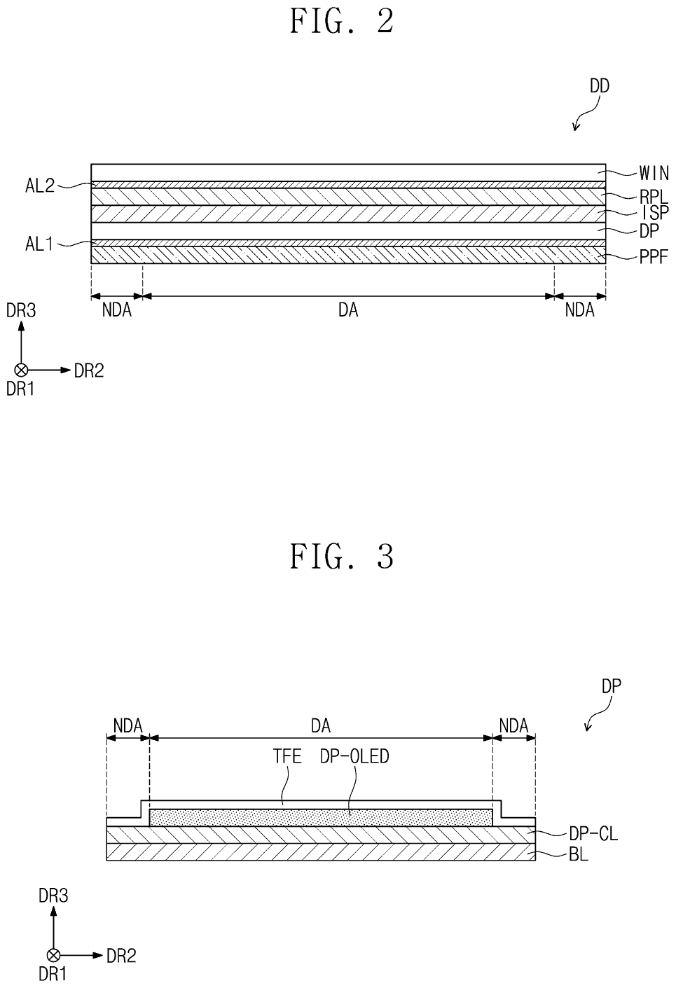

FIG. 2 is a sectional view of the display device illustrated in FIG. 1.

For example, in FIG. 2, a cross-section of the display device DD viewed in the first direction DR1 is illustrated.

Referring to FIG. 2, the display device DD may include a display panel DP, an input sensing part ISP, an anti-reflective layer RPL, a window WIN, a panel protection film PPF, a first adhesive layer AL1, and a second adhesive layer AL2.

The display panel DP may be a flexible display panel. The display panel DP according to an embodiment of the present disclosure may be an emissive display panel. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots and quantum rods. Hereinafter, examples will be described herein in which the display panel DP is an organic light emitting display panel.

The input sensing part ISP may be disposed on the display panel DP. The input sensing part ISP may include a plurality of sensing parts (not illustrated) for sensing an external input in a capacitance type. The input sensing part ISP may be directly manufactured on the display panel DP when the display device DD is manufactured. However, without being limited thereto, the input sensing part ISP may be manufactured as a panel separate from the display panel DP and may be attached to the display panel DP by an adhesive layer.

The anti-reflective layer RPL may be disposed on the input sensing part ISP. The anti-reflective layer RPL may be directly manufactured on the input sensing part ISP when the display device DD is manufactured. However, without being limited thereto, the anti-reflective layer RPL may be manufactured as a separate panel and may be attached to the input sensing part ISP by an adhesive layer.

The anti-reflective layer RPL may be defined as a film for preventing the reflection of external light. The anti-reflective layer RPL may decrease the reflectance of external light incident toward the display panel DP from above the display device DD. The external light may not be visible to the user due to the anti-reflective layer RPL.

When external light travelling toward the display panel DP is reflected from the display panel DP and provided back to the user, the user may visually recognize the external light as in a mirror. To prevent such a phenomenon, for example, the anti-reflective layer RPL may include a plurality of color filters that display the same colors as those of pixels of the display panel DP.

The color filters may filter the external light into the same colors as those of the pixels. In this case, the external light may not be visible to the user. However, without being limited thereto, the anti-reflective layer RPL may include a phase retarder and/or a polarizer to decrease the reflectance of the external light.

The window WIN may be disposed on the anti-reflective layer RPL. The window WIN may protect the display panel DP, the input sensing part ISP, and the anti-reflective layer RPL from external scratches and impacts.

The panel protection film PPF may be disposed under the display panel DP. The panel protection film PPF may protect the bottom of the display panel DP. The panel protection film PPF may include a flexible plastic material such as, for example, polyethylene terephthalate (PET).

The first adhesive layer AL1 may be disposed between the display panel DP and the panel protection film PPF, and the display panel DP and the panel protection film PPF may be bonded to each other by the first adhesive layer AL1. The second adhesive layer AL2 may be disposed between the window WIN and the anti-reflective layer RPL, and the window WIN and the anti-reflective layer RPL may be bonded to each other by the second adhesive layer AL2.

FIG. 3 is a sectional view of the display panel illustrated in FIG. 2.

For example, in FIG. 3, a cross-section of the display panel DP viewed in the first direction DR1 is illustrated.

Referring to FIG. 3, the display panel DP may include a base layer BL, a circuit element layer DP-CL disposed on the base layer BL, a display element layer DP-OLED disposed on the circuit element layer DP-CL, and a thin film encapsulation layer TFE disposed on the display element layer DP-OLED.

The base layer BL may include a display area DA and a non-display area NDA around the display area DA. The base layer BL may include a flexible plastic material such as, for example, glass or polyimide (PI). The display element layer DP-OLED may be disposed in the display area DA.

A plurality of pixels may be disposed in the circuit element layer DP-CL and the display element layer DP-OLED. Each of the pixels may include a transistor disposed in the circuit element layer DP-CL and a light emitting element disposed in the display element layer DP-OLED and connected to the transistor.

The thin film encapsulation layer TFE may be disposed on the circuit element layer DP-CL and cover the display element layer DP-OLED. The thin film encapsulation layer TFE may protect the pixels from moisture, oxygen, and external foreign matter.

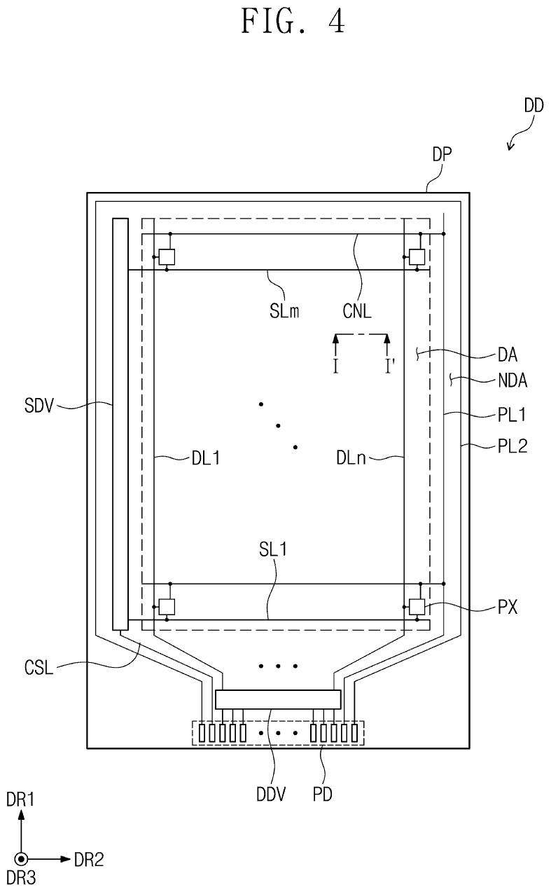

FIG. 4 is a plan view of the display panel illustrated in FIG. 2.

Referring to FIG. 4, the display device DD may include the display panel DP, a scan driver SDV, a data driver DDV, and a plurality of pads PD.

The display panel DP may have a rectangular shape with long sides extending in the first direction DR1 and short sides extending in the second direction DR2. However, the shape of the display panel DP is not limited thereto. The display panel DP may include a display area DA and a non-display area NDA surrounding the display area DA.

The display panel DP may include a plurality of pixels PX, a plurality of scan lines SL1 to SLm, a plurality of data lines DL1 to DLn, a control line CSL, a first power line PL1, a second power line PL2, and connecting lines CNL. “m” and “n” are natural numbers.

The pixels PX may be disposed in the display area DA. The pixels PX may be arranged in a matrix form. However, the arrangement of the pixels PX is not limited thereto.

The scan driver SDV may be disposed in the non-display area NDA adjacent to one of the long sides of the display panel DP. The scan driver SDV may be adjacent to the left side of the display panel DP when viewed from above the plane.

The data driver DDV may be disposed in the non-display area NDA adjacent to one of the short sides of the display panel DP. The data driver DDV may be adjacent to the lower end of the display panel DP when viewed from above the plane.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV.

The first power line PL1 may extend in the first direction DR1 and may be disposed in the non-display area NDA. The first power line PL1 may be adjacent to the long side of the display panel DP where the scan driver SDV is not disposed.

The connecting lines CNL may extend in the second direction DR2 and may be arranged in the first direction DR1. The connecting lines CNL may be connected to the first power line PL1 and the pixels PX. A first voltage may be applied to the pixels PX through the first power line PL1 and the connecting lines CNL connected with each other.

The second power line PL2 may be disposed in the non-display area NDA and may extend along the long sides of the display panel DP and the other short side of the display panel DP where the data driver DDV is not disposed. The second power line PL2 may be disposed outward of the scan driver SDV.

Although not illustrated, the second power line PL2 may extend toward the display area DA and may be connected to the pixels PX. A second voltage may be applied to the pixels PX through the second power line PL2.

The control line CSL may be connected to the scan driver SDV and

may extend toward the lower end of the display panel DP. A control signal for controlling an operation of the scan driver SDV may be provided to the scan driver SDV through the control line CSL.

The pads PD may be disposed in the non-display area NDA adjacent to the lower end of the display panel DP and may be closer to the lower end of the display panel DP than the data driver DDV. The data driver DDV, the first power line PL1, the second power line PL2, and the control line CSL may be connected to the pads PD. The data lines DL1 to DLn may be connected to the data driver DDV, and the data driver DDV may be connected to the pads PD corresponding to the data lines DL1 to DLn.

Although not illustrated, the display device DD may further include a timing controller for controlling operations of the scan driver SDV and the data driver DDV and a voltage generator for generating the first voltage and the second voltage. The timing controller and the voltage generator may be mounted on a printed circuit board and may be connected to the pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn.

The pixels PX may receive the data voltages in response to the scan signals. The pixels PX may display an image by emitting light having luminance corresponding to the data voltages.

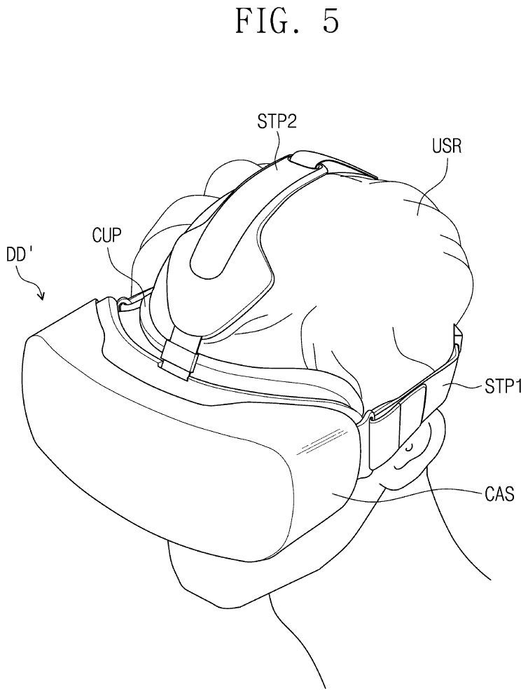

FIG. 5 is a view illustrating a display device according to an embodiment of the present disclosure.

Referring to FIG. 5, the display device DD′ according to an embodiment of the present disclosure may be defined as a head-mounted display device. The display device DD′ may be worn on the head of a user USR.

The display device DD′ may block a peripheral view of the user USR and may provide an image to the user USR. The display device DD′ may provide virtual reality to the user USR.

The display device DD′ may include a casing CAS, a cushion CUP, and straps STP1 and STP2. The casing CAS may be worn on the user USR. A display panel DP that displays an image and an acceleration sensor (not illustrated) may be accommodated in the casing CAS. The display panel DP may be the display panel DP illustrated in FIG. 4.

The acceleration sensor may sense a movement of the user USR and may transfer a certain signal to the display panel DP. Accordingly, the display panel DP may provide an image corresponding to a change in the gaze of the user USR. Thus, the user USR may experience virtual reality similar to actual reality.

The cushion CUP may be disposed between the casing CAS and the user USR. The cushion CUP may include a material that is free to deform. For example, the cushion CUP may include a polymer resin (e.g., polyurethane, polycarbonate, polypropylene, or polyethylene). Alternatively, the cushion CUP may include a sponge formed by causing liquid rubber, a urethane-based material, or an acrylic material to foam.

The cushion CUP may bring the casing CAS into close contact with the user USR to improve the wearing comfort of the user USR. The cushion CUP may be detachable from the casing CAS.

The straps STP1 and STP2 may be coupled with the casing CAS to enable the casing CAS to be easily worn on the user USR. The straps STP1 and STP2 may include the first strap STP1 and the second strap STP2.

The first strap STP1 may be worn along the circumference of the head of the user USR. The first strap STP1 may fix the casing CAS to the user USR to bring the casing CAS into close contact with the head of the user US.

The second strap STP2 may connect the casing CAS and the first strap STP1 along the upper part of the head of the user USR. The second strap STP2 may prevent the casing CAS from slipping down.

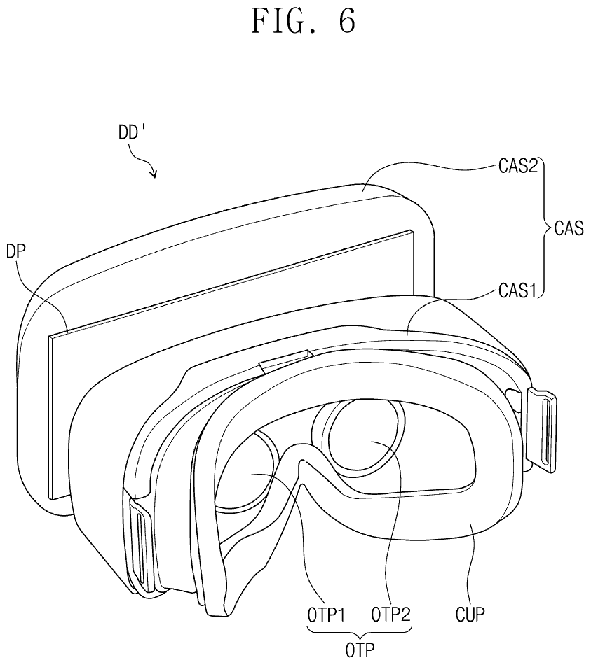

FIG. 6 is an exploded perspective view of the display device illustrated in FIG. 5.

Referring to FIG. 6, the casing CAS may include a first casing CAS1 and a second casing CAS2. The first casing CAS1 and the second casing CAS2 may be separated from each other.

The display panel DP may be disposed between the first casing CAS1 and the second casing CAS2. The first casing CAS1 and the second casing CAS2 may be coupled with each other, and accordingly the display panel DP may be accommodated in the casing CAS. For example, the display panel DP may provide a left eye image and a right eye image to the user USR. Accordingly, the display panel DP may provide a stereoscopic image to the user USR.

An optical system OTP may be disposed in the first casing CAS1. The optical system OTP may magnify an image provided from the display panel DP. The optical system OTP may be disposed between the display panel DP and the eyes of the user USR. The optical system OTP may include a left-eye optical system OTP1 and a right-eye optical system OTP2. The left-eye optical system OTP1 may magnify and provide the image to the left pupil of the user USR, and the right-eye optical system OTP2 may magnify and provide the image to the right pupil of the user USR.

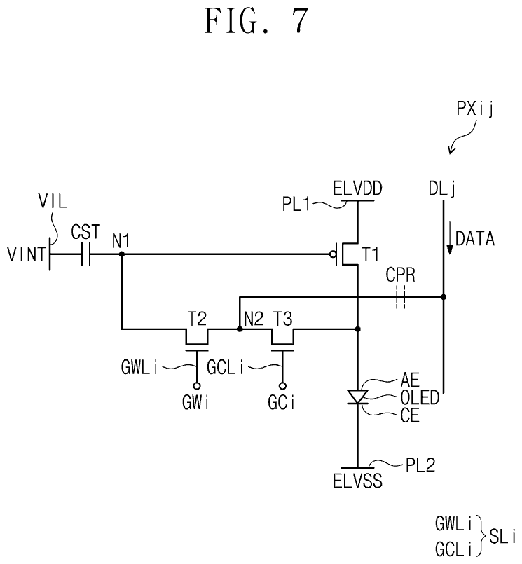

FIG. 7 is a view illustrating an equivalent circuit of one of the pixels illustrated in FIG. 4.

For example, in FIG. 7, a pixel PXij connected to the i^{th} scan line SLi and the j^{th} data line DLj is illustrated. “i” and “j” are natural numbers. Hereinafter, for convenience of description, the ordinal numbers i^{th} and j^{th} will be omitted.

Referring to FIG. 7, the pixel PXij may include a first transistor T1, a second transistor T2, a third transistor T3, a light emitting element OLED, and a capacitor CST.

The scan line SLi may include a write scan line GWLi and a compensation scan line GCLi. The write scan line GWLi may receive a write scan signal GWi, and the compensation scan line GCLi may receive a compensation scan signal GCi.

A parasitic capacitor CPR may be unintentionally formed between a second node N2 between the second transistor T2 and the third transistor T3 and the data line DLj. However, the parasitic capacitor CPR is not a component of the pixel PXij, and therefore description of the parasitic capacitor CPR will be omitted in the description of an operation of the pixel PXij.

The light emitting element OLED may be defined as an organic light emitting element. The light emitting element OLED may include an anode AE and a cathode CE. The anode AE may be connected to the first power line PL1 through the first transistor T1. The cathode CE may be connected to the second power line PL2. The first power line PL1 may receive a first voltage ELVDD. The second power line PL2 may receive a second voltage ELVSS having a lower level than the first voltage ELVDD.

The first transistor T1 may be a PMOS transistor. The second transistor T2 and the third transistor T3 may be NMOS transistors. The first transistor T1 may include a silicon semiconductor, and the second transistor T2 and the third transistor T3 may include an oxide semiconductor.

Each of the first transistor T1, the second transistor T2, and the third transistor T3 may include a source electrode, a drain electrode, and a gate electrode. Hereinafter, in FIG. 7, for convenience, one of the source electrode and the drain electrode is defined as a first electrode, and the other is defined as a second electrode. In some aspects, the gate electrode is defined as a control electrode.

The first transistor T1 may be defined as a drive transistor, and the second transistor T2 may be defined as a switching transistor. The third transistor T3 may be defined as a compensation transistor.

The first transistor T1 may be connected to the first power line PL1 and the anode AE of the light emitting element OLED and may be switched by a voltage of a first node N1. The first transistor T1 may include the first electrode connected to the first power line PL1, the second electrode connected to the anode AE of the light emitting element OLED, and the control electrode connected to the first node N1. The first transistor T1 may be turned on by the voltage of the first node N1. The first node N1 may be substantially defined as the control electrode of the first transistor T1.

The second transistor T2 may be connected to the first node N1 and the second node N2. Specifically, the second transistor T2 may be connected to the gate electrode of the first transistor T1 and the data line DLj. The second transistor T2 may be switched by the write scan signal GWi.

The second transistor T2 may include the first electrode connected to the first node N1, the second electrode connected to the second node N2, and the control electrode connected to the write scan line GWLi. The second transistor T2 may be turned on by the write scan signal GWi applied through the write scan line GWLi.

The third transistor T3 may be connected to the second node N2 and the anode AE of the light emitting element OLED and may be switched by the compensation scan signal GCi. The third transistor T3 may include the first electrode connected to the second node N2, the second electrode connected to the anode AE of the light emitting element OLED, and the control electrode connected to the compensation scan line GCLi. The third transistor T3 may be turned on by the compensation scan signal GCi applied through the compensation scan line GCLi.

The data line DLj may be connected to the second node N2. Accordingly, the data line DLj may be connected to the second electrode of the second transistor T2 and the first electrode of the third transistor T3. The data line DLj may receive a data signal DATA.

The anode AE of the light emitting element OLED may be connected to the first power line PL1 through the first transistor T1, and the cathode CE of the light emitting element OLED may be connected to the second power line PL2.

The capacitor CST may include a first electrode connected to an initialization line VIL and a second electrode connected to the first node N1. The initialization line VIL may receive an initialization voltage VINT.

The write scan signal GWi applied to the control electrode of the second transistor T2 may be a global clock signal for simultaneous emission. In an example in which the display device DD operates in a simultaneous emission method, the write scan signal GWi, which is the global clock signal, may be commonly applied to the pixels PX.

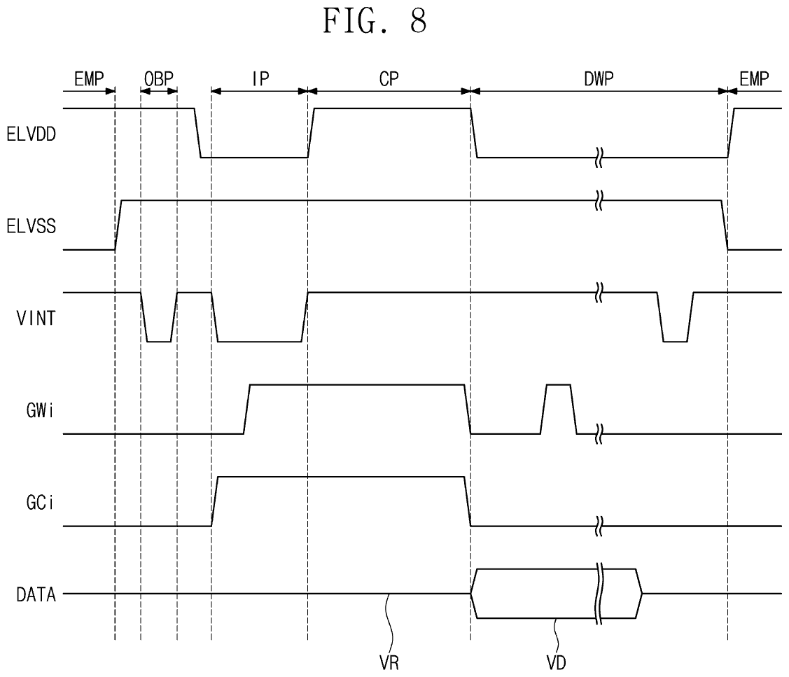

FIG. 8 is a timing chart of signals for operating the pixel illustrated in FIG. 7.

Referring to FIGS. 7 and 8, an operating period of the pixel PXij may include an on-bias period OBP, an initialization period IP, a compensation period CP, a data write period DWP, and an emission period EMP.

The pixel PXij may perform an on-bias operation in the on-bias period OBP and may perform an initialization operation in the initialization period IP. The pixel PXij may perform a threshold voltage compensation operation in the compensation period CP, may perform a data write operation in the data write period DWP, and may perform an emission operation in the emission period EMP.

In the on-bias period OBP, the first voltage ELVDD may have a high voltage level, the second voltage ELVSS may have a high voltage level, and the initialization voltage VINT may have a low voltage level. In the on-bias period OBP, the write scan signal GWi and the compensation scan signal GCi may have a low level (e.g., a deactivation level), and the data signal DATA may have a reference voltage VR having a preset level.

The terms “high voltage level” and “low voltage levels” are relative terms describing levels of voltages which, when applied to a component (e.g., transistor) described herein, activate the component (e.g., turn “ON” the component) or deactivate the component (e.g., turn “OFF” the component).

In this case, the on-bias operation may be performed on the pixel PXij, and accordingly the voltage characteristic curve of the first transistor T1 may be initialized to an on-bias state irrespective of the data signal DATA supplied in the previous frame. Thus, the pixel PXij may generate a desired luminance irrespective of the data signal DATA supplied in the previous frame.

In the on-bias period OBP, the initialization voltage VINT having the low voltage level may be transferred to the gate terminal of the first transistor T1, but since both the first voltage ELVDD and the second voltage ELVSS have the high voltage level, the first transistor T1 may not be turned on. The second transistor T2 and the third transistor T3 may be turned off depending on the deactivated write scan signal GWi and the deactivated compensation scan signal GCi.

Thereafter, in the initialization period IP, the first voltage ELVDD may have a low voltage level, the second voltage ELVSS may have a high voltage level, and the initialization voltage VINT may have a low voltage level. In the initialization period IP, the write scan signal GWi may transition from the low level to a high level (e.g., an activation level), the compensation scan signal GCi may have a high level (e.g., an activation level), and the data signal DATA may have the reference voltage VR.

Accordingly, the second transistor T2 may be turned off and then turned on, and the third transistor T3 may be turned on. Since the second transistor T2 and the third transistor T3 are turned on, the first node N1 may be connected to the second node N2, and the second node N2 may be connected to the anode AE of the light emitting element OLED. Depending on the initialization voltage VINT, the first node N1 (that is, the control electrode of the first transistor T1) may be initialized, the second node N2 connected to the first node N1 may be initialized, and the anode AE of the light emitting element OLED connected to the second node N2 may be initialized.

Thereafter, in the compensation period CP, the first voltage ELVDD may have a high voltage level, the second voltage ELVSS may have a high voltage level, and the initialization voltage VINT may have a high voltage level. In the compensation period CP, the write scan signal GWi may have a high level, the compensation scan signal GCi may have a high level, and the data signal DATA may have the reference voltage VR.

The first transistor T1, the second transistor T2, and the third transistor T3 may be connected in the form of a diode. In this case, a voltage reflecting the threshold voltage of the first transistor T1 may be stored at the first node N1, and accordingly the characteristic deviation depending on the threshold voltage of the first transistor T1 may be eliminated. The operation of connecting the first transistor T1 in the form of a diode may be defined as the threshold voltage compensation operation.

Thereafter, in the data write period DWP, the first voltage ELVDD may have a low voltage level, and the second voltage ELVSS may have a high voltage level. In the data write period DWP, the initialization voltage VINT may transition from the high voltage level to a low voltage level and then may transition from the low voltage level to a high voltage level after a certain time elapses.

In the data write period DWP, the write scan signal GWi may transition from a low level to a high level and then may transition from the high level to a low level after a certain time (e.g., a data write operation time) elapses. In the data write period DWP, the compensation scan signal GCi may have a low level, and the data signal DATA may have a data voltage VD having a level corresponding to a certain grayscale.

The second transistor T2 may be turned on during the activation period (e.g., the high level) of the write scan signal GWi, and the third transistor T3 may be turned off. During the data write operation time when the second transistor T2 is turned on, the data signal DATA may be stored in the capacitor CST.

Thereafter, in the emission period EMP, the first voltage ELVDD may have a high voltage level, the second voltage ELVSS may have a low voltage level, and the initialization voltage VINT may have a high voltage level. The write scan signal GWi may have a low level, the compensation scan signal GCi may have a low level, and the data signal DATA may have the reference voltage VR.

In this case, the first transistor T1 may be turned on based on the data signal DATA stored in the capacitor CST. Accordingly, a current may flow to the light emitting element OLED, and the light emitting element OLED may emit light.

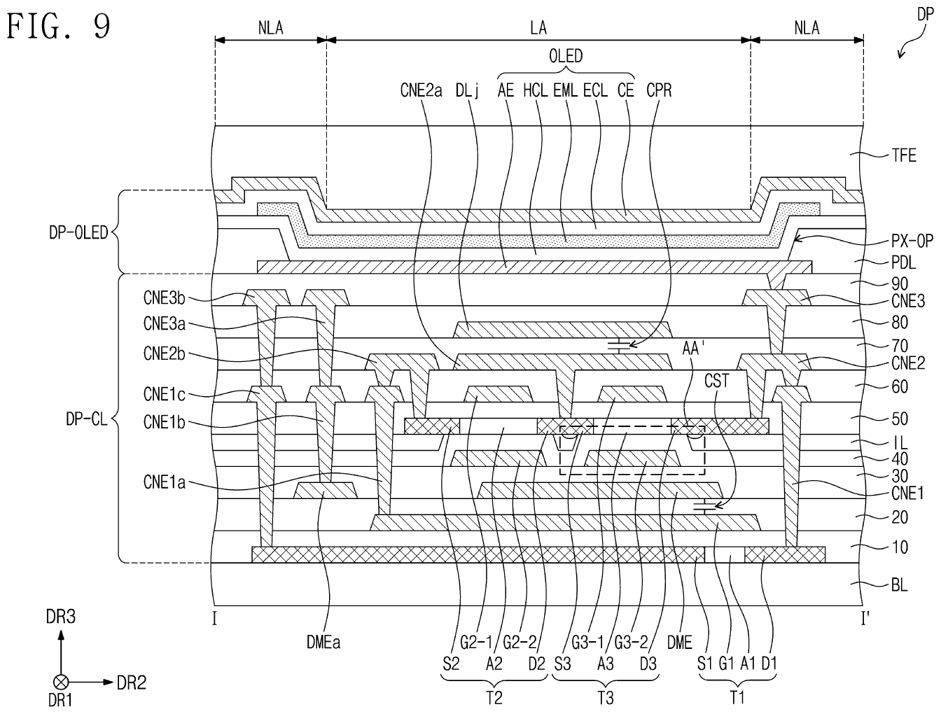

FIG. 9 is a schematic sectional view of the pixel illustrated in FIG. 7. Specifically, FIG. 9 illustrates a cross-section of the display panel DP in accordance with one or more embodiments of the present disclosure, taken along line I-I′ of FIG. 4.

Referring to FIG. 9, the light emitting element OLED may include a first electrode AE, a second electrode CE, a hole control layer HCL, an electron control layer ECL, and an emissive layer EML. The first electrode AE may be the anode AE illustrated in FIG. 7, and the second electrode CE may be the cathode CE illustrated in FIG. 7. The second electrode CE may be disposed over the first electrode AE, and the hole control layer HCL, the electron control layer ECL, and the emissive layer EML may be disposed between the first electrode AE and the second electrode CE.

The display area DA may include an emissive area LA and a non-emissive area NLA adjacent to the emissive area LA. The light emitting element OLED may be disposed in the emissive area LA.

The layers from the base layer BL to the ninth insulating layer 90 may be defined as the circuit element layer DP-CL. The layer in which the light emitting element OLED is disposed may be defined as the display element layer DP-OLED.

The first transistor T1 may be disposed on the base layer BL, and the second transistor T2 and the third transistor T3 may be disposed over the first transistor T1.

A first semiconductor layer S1, A1, and D1 of the first transistor T1 may be disposed on the base layer BL. Although not illustrated, a buffer layer may be further disposed on the base layer BL. The first semiconductor layer S1, A1, and D1 may include poly silicon. However, without being limited thereto, the first semiconductor layer S1, A1, and D1 may include amorphous silicon.

The first semiconductor layer S1, A1, and D1 may include a first source area S1, a first channel area A1, and a first drain area D1. The first channel area A1 may be disposed between the first source area S1 and the first drain area D1. The first source area S1 may correspond to the first electrode of the first transistor T1 described herein. The first drain area D1 may correspond to the second electrode of the first transistor T1 described herein.

The first source area S1 and the first drain area D1 may have conductivity through a doping process and may substantially serve as the source electrode and the drain electrode of the first transistor T1. The first channel area A1 may substantially correspond to the active of the first transistor T1.

The first insulating layer 10 may be disposed on the base layer BL and cover the first semiconductor layer S1, A1, and D1. A first gate electrode G1 of the first transistor T1 may be disposed on the first insulating layer 10. The first gate electrode G1 may overlap the first channel area A1 when viewed from above the plane. The first gate electrode G1 may be the control electrode of the first transistor T1 described herein and may be connected to the first node N1 (refer to FIG. 7). Substantially, the first gate electrode G1 may serve as the first node N1.

The second insulating layer 20 may be disposed on the first insulating layer 10 and cover the first gate electrode G1. A dummy electrode DME may be disposed on the second insulating layer 20. The dummy electrode DME, together with the first gate electrode G1, may form the above-described capacitor CST. The first gate electrode G1 may define the first electrode of the capacitor CST, and the dummy electrode DME may define the second electrode of the capacitor CST. The first gate electrode G1 may be referred to as a first-first gate electrode, and the dummy electrode DME may be referred to as a first-second gate electrode. A dummy electrode DMEa may be further disposed on the second insulating layer 20. The third insulating layer 30 may be disposed on the second insulating layer 20 and cover the dummy electrodes DME and DMEa.

A second-second gate electrode G2-2 of the second transistor T2 and a third-second gate electrode G3-2 of the third transistor T3 may be disposed on the third insulating layer 30. The fourth insulating layer 40 may be disposed on the third insulating layer 30 and cover the second-second gate electrode G2-2 and the third-second gate electrode G3-2.

According to an embodiment of the present disclosure, an inorganic layer IL may be disposed on the fourth insulating layer 40. The fourth insulating layer 40 and the inorganic layer IL may provide a flat upper surface. The inorganic layer IL may include the same material as the fourth insulating layer 40. For example, the inorganic layer IL may include an inorganic material. A second semiconductor layer S2, A2, and D2 of the second transistor T2 and a third semiconductor layer S3, A3, and D3 of the third transistor T3 may be disposed on the fourth insulating layer 40 and the inorganic layer IL. The second semiconductor layer S2, A2, and D2 and the third semiconductor layer S3, A3, and D3 may include an oxide semiconductor formed of metal oxide. The oxide semiconductor may include a crystalline or amorphous oxide semiconductor.

Each of the second semiconductor layer S2, A2, and D2 and the third semiconductor layer S3, A3, and D3 may include a plurality of areas distinguished from one another depending on whether the metal oxide is reduced. Areas where the metal oxide is reduced (hereinafter, referred to as the reduced areas) have a higher conductivity than an area where the metal oxide is not reduced (hereinafter, referred to as the non-reduced area). The reduced areas may substantially serve as the source electrode or the drain electrode of each of the second transistor T2 and the third transistor T3. The non-reduced area may substantially correspond to the active (or, channel) of each of the second transistor T2 and the third transistor T3.

The third semiconductor layer S3, A3, and D3 may extend from the second semiconductor layer S2, A2, and D2. A second channel area A2 may be disposed between a second source area S2 and a second drain area D2, and a third channel area A3 may be disposed between a third source area S3 and a third drain area D3.

The second-second gate electrode G2-2 may have a larger area than the second channel area A2 and may cover the second channel area A2 from below the second channel area A2. The third-second gate electrode G3-2 may have a larger area than the third channel area A3 and may cover the third channel area A3 from below the third channel area A3.

The second-second gate electrode G2-2 may block light provided toward the second channel area A2 from below the base layer BL. The third-second gate electrode G3-2 may block light provided toward the third channel area A3 from below the base layer BL.

When light is provided to the second channel area A2 and the third channel area A3, the threshold voltage characteristics of the second transistor T2 and the third transistor T3 may be changed (e.g., the threshold voltages may be shifted) by the light. To prevent such a phenomenon, the second-second gate electrode G2-2 and the third-second gate electrode G3-2 may block light provided toward the second channel area A2 and the third channel area A3 from below the base layer BL.

The second node N2 (refer to FIG. 7) may be defined between the second semiconductor layer S2, A2, and D2 and the third semiconductor layer S3, A3, and D3. A portion of the semiconductor layer between the third source area S3 and the second drain area D2 may be defined as the second node N2. That is, the second semiconductor layer S2, A2, and D2 and the third semiconductor layer S3, A3, and D3 may be connected to the second node N2. The fifth insulating layer 50 may be disposed on the fourth insulating layer 40 and the inorganic layer IL and cover the second semiconductor layer S2, A2, and D2 and the third semiconductor layer S3, A3, and D3.

A second-first gate electrode G2-1 and a third-first gate electrode G3-1 may be disposed on the fifth insulating layer 50. The second-first gate electrode G2-1 may overlap the second channel area A2 when viewed from above the plane. The third-first gate electrode G3-1 may overlap the third channel area A3 when viewed from above the plane.

Depending on the described structure, the second-first gate electrode G2-1 may be disposed over the second semiconductor layer S2, A2, and D2, and the second-second gate electrode G2-2 may be disposed under the second semiconductor layer S2, A2, and D2. The third-first gate electrode G3-1 may be disposed over the third semiconductor layer S3, A3, and D3, and the third-second gate electrode G3-2 may be disposed under the third semiconductor layer S3, A3, and D3.

The second-second gate electrode G2-2 and the third-second gate electrode G3-2 may be disposed in different layers. For example, the second-second gate electrode G2-2 may be disposed in a layer over the third-second gate electrode G3-2.

First connecting electrodes CNE1, CNE1a, CNE1b, and CNE1c may be further disposed on the fifth insulating layer 50. The first connecting electrode CNE1 may be electrically connected with the first drain area D1 of the first transistor T1 through a contact hole that penetrates the first to fifth insulating layers 10, 20, 30, 40, and 50 and the inorganic layer IL. The first connecting electrode CNE1a may be electrically connected with the first gate electrode G1 of the first transistor T1 through a contact hole that penetrates the second to fifth insulating layers 20, 30, 40, and 50 and the inorganic layer IL. The first connecting electrode CNE1b may be electrically connected with the dummy electrode DMEa through a contact hole that penetrates the third to fifth insulating layers 30, 40, and 50 and the inorganic layer IL. The first connecting electrode CNE1c may be electrically connected with the first source area S1 of the first transistor T1 through a contact hole that penetrates the first to fifth insulating layers 10, 20, 30, 40, and 50 and the inorganic layer IL.

The sixth insulating layer 60 may be disposed on the fifth insulating layer 50 and cover the second-first gate electrode G2-1, the third-first gate electrode G3-1, and the first connecting electrodes CNE1, CNE1a, CNE1b, and CNE1c. Second connecting electrodes CNE2, CNE2a, and CNE2b may be disposed on the sixth insulating layer 60. The second connecting electrode CNE2 may electrically connect the third drain area D3 of the third transistor t3 and the first drain area D1 of the first transistor T1. The second connecting electrode CNE2a may be electrically connected to the second node N2 (refer to FIG. 7), which is a semiconductor layer between the third source area S3 and the second drain area D2, through a contact hole that penetrates the fifth insulating layer 50 and the sixth insulating layer 60. The second connecting electrode CNE2b may electrically connect the second source area S2 of the second transistor T2 and the first gate electrode G1.

The data line DLj may be disposed on the seventh insulating layer 70. The data line DLj, together with the second connecting electrode CNE2a, may form the above-described parasitic capacitor CPR. However, unlike that illustrated in the present disclosure, the parasitic capacitor CPR may not be formed.

The eighth insulating layer 80 may be disposed on the seventh insulating layer 70 and cover the data line DLj. Third connecting electrodes CNE3, CNE3a, and CNE3b may be disposed on the eighth insulating layer 80. The third connecting electrode CNE3 may electrically connect the anode AE and the second connecting electrode CNE2 through a contact hole that penetrates the seventh insulating layer 70 and the eighth insulating layer 80. That is, the anode AE and the first drain area D1 of the first transistor T1 may be electrically connected with each other through the first to third connecting electrodes CNE1, CNE2, and CNE3. The third connecting electrode CNE3a may be electrically connected with the first connecting electrode CNE1b through a contact hole that penetrates the sixth to eighth insulating layers 60, 70, and 80. The third connecting electrode CNE3a may be electrically connected to the initialization line VIL illustrated in FIG. 7. The third connecting electrode CNE3b may be electrically connected with the first connecting electrode CNE1c through a contact hole that penetrates the sixth to eighth insulating layers 60, 70, and 80. The third connecting electrode CNE3b may be electrically connected to the first power line PL1 illustrated in FIG. 7. That is, the first voltage ELVDD may be applied to the first source area S1 of the first transistor T1 through the first connecting electrode CNE1c and the third connecting electrode CNE3b.

In FIG. 9, the circuit element layer DP-CL in accordance with one or more embodiments of the present disclosure may include the first to third transistors T1, T2, and T3, and the second transistor T2 and the third transistor T3 may be disposed over the first transistor T1 and may overlap the first transistor T1 when viewed from above the plane. However, embodiments of the present disclosure are not limited thereto, and the circuit element layer DP-CL may further include a fourth transistor disposed over the second transistor T2 and the third transistor T3. Accordingly, the plurality of transistors may be disposed in the limited area, and thus the display device DD (refer to FIG. 1) with high resolution may be provided.

A pixel defining layer PDL exposing a certain portion of the first electrode AE may be disposed on the first electrode AE and the ninth insulating layer 90. An opening PX-OP for exposing the certain portion of the first electrode AE may be defined in the pixel defining layer PDL.

The hole control layer HCL may be disposed on the first electrode AE and the pixel defining layer PDL. The hole control layer HCL may be commonly disposed in the emissive area LA and the non-emissive area NLA. The hole control layer HCL may include a hole transport layer and a hole injection layer.

The emissive layer EML may be disposed on the hole control layer HCL. The emissive layer EML may be disposed in an area corresponding to the opening PX_OP. The emissive layer EML may include an organic material and/or an inorganic material. The emissive layer EML may generate one of red light, green light, and blue light.

The electron control layer ECL may be disposed on the emissive layer EML and the hole control layer HCL. The electron control layer ECL may be commonly disposed in the emissive area LA and the non-emissive area NLA. The electron control layer ECL may include an electron transport layer and an electron injection layer.

The second electrode CE may be disposed on the electron control layer ECL. The second electrode CE may be commonly disposed in the pixels PX. That is, the second electrode CE may be commonly disposed over the emissive layers EML of the pixels PX.

The thin film encapsulation layer TFE may be disposed on the light emitting element OLED. The thin film encapsulation layer TFE may include an inorganic layer, an organic layer, and an inorganic layer sequentially stacked one above another. The inorganic layers may include an inorganic material and may protect the pixels PX from moisture/oxygen. The organic layer may include an organic material and may protect the pixels PX from foreign matter such as, for example, dust particles.

The first voltage ELVDD may be applied to the first electrode AE, and the second voltage EVLSS may be applied to the second electrode CE. Holes and electrons injected into the emissive layer EML may be combined to form excitons, and the light emitting element OLED may emit light as the excitons transition to a ground state. An image may be displayed as the light emitting element OLED emits the light.

FIG. 10 is an enlarged view of area AA′ illustrated in FIG. 9.

Referring to FIG. 10, a first metal layer MTL1 may be disposed on the third insulating layer 30. The first metal layer MTL1 may correspond to the third-second gate electrode G3-2 of FIG. 9. However, embodiments of the present disclosure are not limited thereto, and the first metal layer MTL1 may correspond to the metal layers illustrated in FIG. 9, for example, the gate electrodes G1, G2-1, G2-2, and G3-2, the connecting electrodes CNE1, CNE1a, CNE1b, CNE1c, CNE2, CNE2a, CNE2b, CNE3, CNE3a, and CNE3b, and the semiconductor layers.

The fourth insulating layer 40 may be disposed on the first metal layer MTL1, and the inorganic layer IL may be disposed on the fourth insulating layer 40. The fourth insulating layer 40 may include a first upper surface US1 that overlaps the inorganic layer IL and a second upper surface US2 that does not overlap the inorganic layer IL and overlaps the first metal layer MTL1. The inorganic layer IL may be directly disposed on the first upper surface US1.

Although not illustrated, the base layer BL (refer to FIG. 9) in accordance with one or more embodiments of the present disclosure may include a first area AA1 and a second area AA2. According to an embodiment of the present disclosure, the first metal layer MTL1 may be disposed in the first area AA1, and the inorganic layer IL may be disposed in the second area AA2 and not in the first area AA1. The first metal layer MTL1 and the inorganic layer IL may not overlap each other when viewed from above the plane. The first metal layer MTL1 may have a first thickness TH1, and the inorganic layer IL may have a second thickness TH2. The first thickness TH1 and the second thickness TH2 may be equal to each other. The first thickness TH1 and the second thickness TH2 may range from 3500 Å to 4500 Å. A second metal layer MTL2 may be disposed on the inorganic layer IL and the fourth insulating layer 40. Specifically, the second metal layer MTL2 may be directly disposed on the second upper surface US2 of the fourth insulating layer 40. The inorganic layer IL and the fourth insulating layer 40 may provide a flat upper surface for the second metal layer MTL2. That is, the upper surface of the inorganic layer IL and the second upper surface US2 of the fourth insulating layer 40 may be formed parallel to each other and provide a flat upper surface for the second metal layer MTL2.

When the inorganic layer IL is not disposed in the second area AA2, there is a risk that the second metal layer MTL2 may be disconnected due to a step caused by the first metal layer MTL1. However, since the second metal layer MTL2 in accordance with one or more embodiments of the present disclosure is disposed on the flat upper surface provided by the inorganic layer IL and the fourth insulating layer 40, the risk of disconnection may be reduced, and thus the reliable display device DD (refer to FIG. 1) may be provided. The second metal layer MTL2 in accordance with one or more embodiments of the present disclosure may correspond to the third semiconductor layer S3, A3, and D3 of FIG. 9. However, embodiments of the present disclosure are not limited thereto.

According to an embodiment of the present disclosure, a depression portion DEP may be defined in the inorganic layer IL. The depression portion DEP may be concavely formed in the thickness direction of the inorganic layer IL. The depression portion DEP may be provided in plural. The depression portions DEP may be adjacent to the first metal layer MTL1.

The depression portions DEP may be formed in the process of forming the inorganic layer IL. A process of forming the depression portions DEP will be described herein in detail in a method of manufacturing the display device DD (refer to FIG. 1).

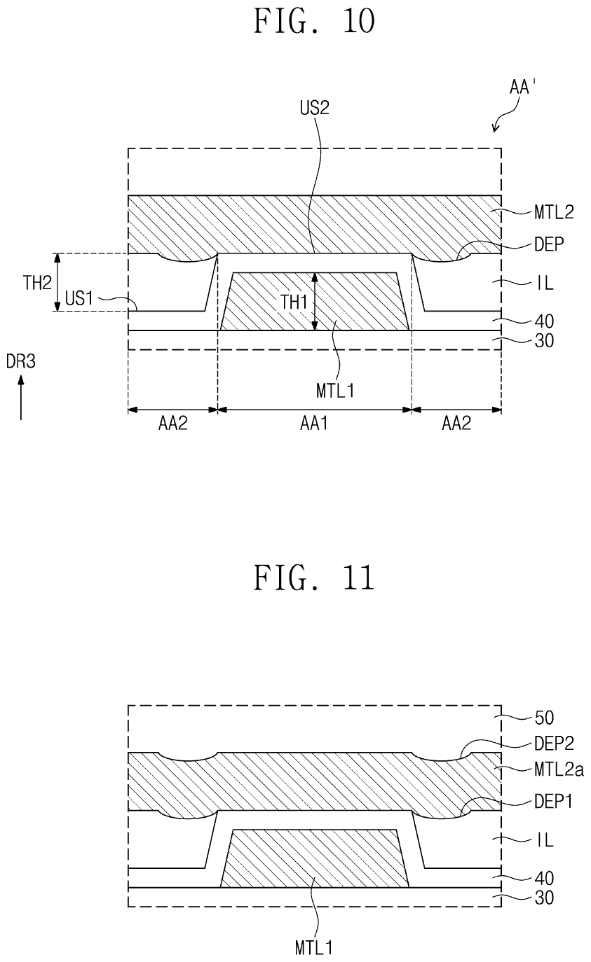

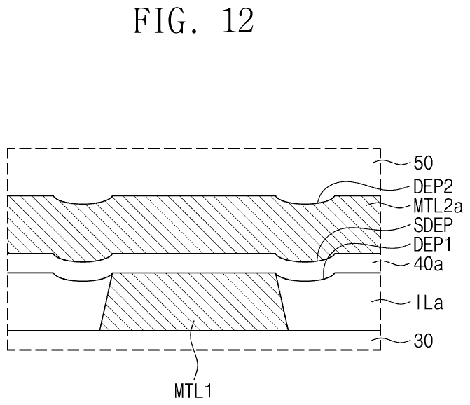

FIGS. 11 and 12 are enlarged views illustrating a portion of a cross-section of the display panel according to an embodiment of the present disclosure.

Referring to FIG. 11, a second metal layer MTL2a may be disposed on the fourth insulating layer 40 and the inorganic layer IL, and the fifth insulating layer 50 may be disposed on the second metal layer MTL2a.

A first depression portion DEP1 may be defined in the inorganic layer IL, and a second depression portion DEP2 may be defined on the second metal layer MTL2a. The first depression portion DEP1 may be the same as the depression portion DEP illustrated in FIG. 10. The second depression portion DEP2 may correspond to the first depression portion DEP1 and may have the same shape as the first depression portion DEP1.

Referring to FIG. 12, an inorganic layer ILa may be directly disposed on the third insulating layer 30. The inorganic layer ILa may make direct contact with the first metal layer MTL1. That is, the side surface of the inorganic layer ILa may make direct contact with the first metal layer MTL1.

A fourth insulating layer 40a may be directly disposed on the inorganic layer ILa and the first metal layer MTL1. According to an embodiment of the present disclosure, a sub-depression portion SDEP may be defined on the fourth insulating layer 40a. The sub-depression portion DDEP may correspond to the first depression portion DEP1 and may have the same shape as the first depression portion DEP1.

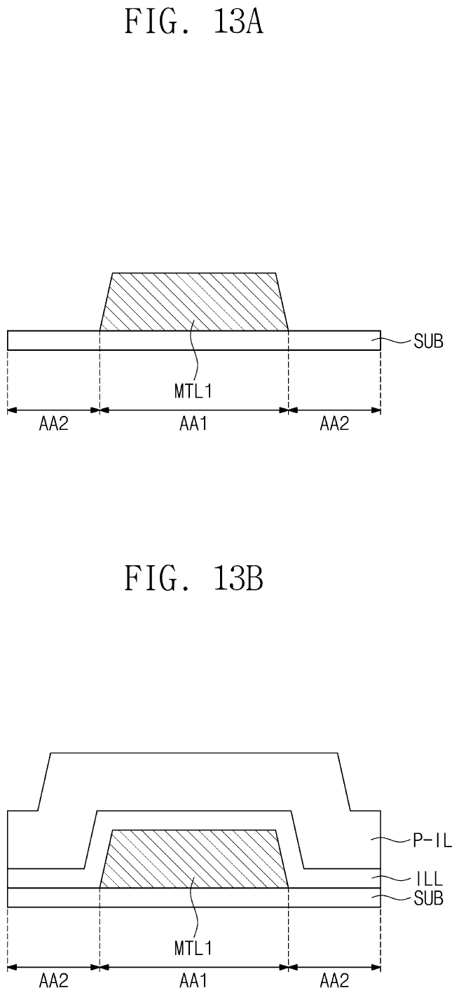

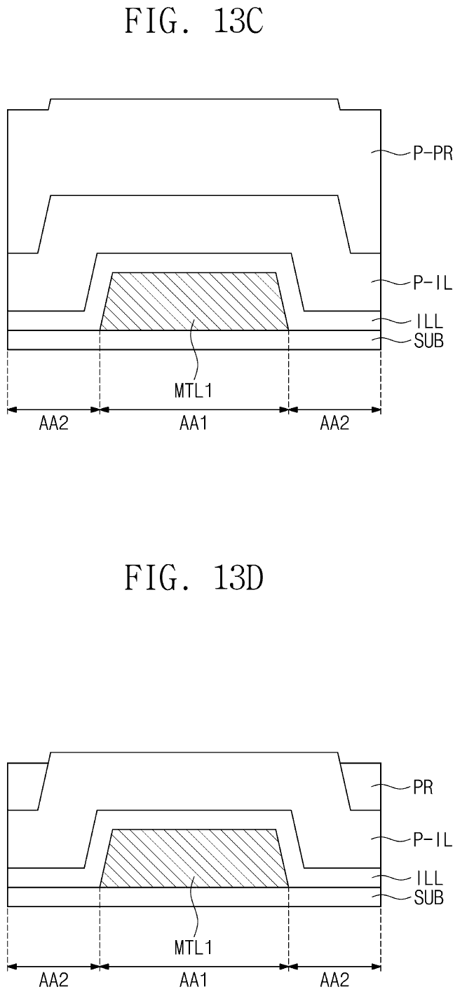

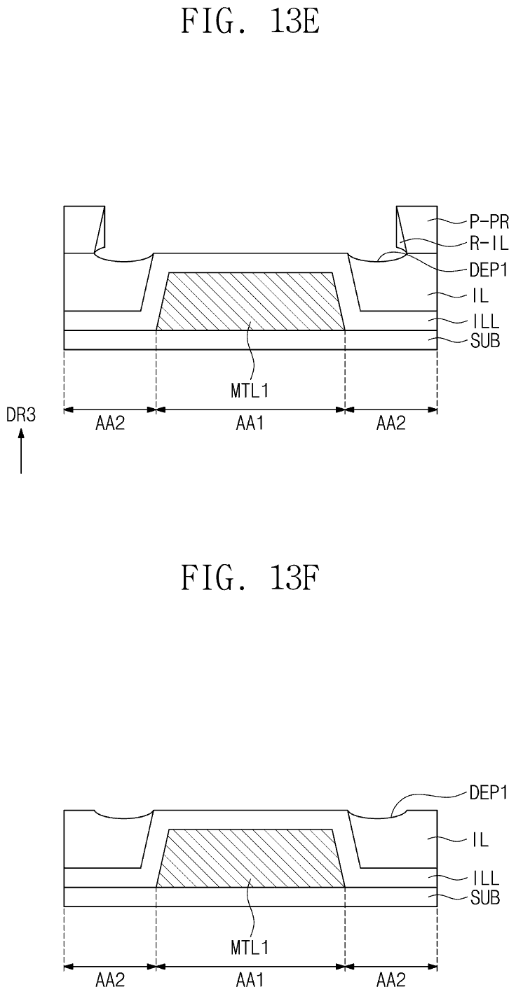

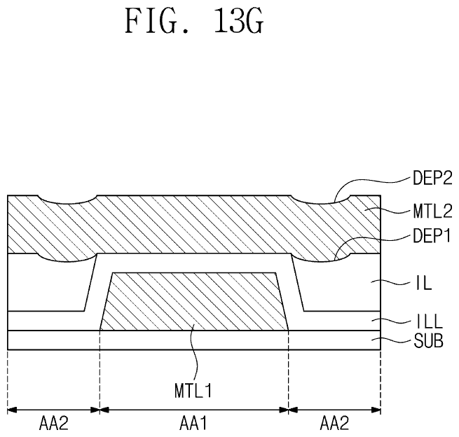

FIGS. 13A to 13G are process views illustrating a portion of a manufacturing process of the display device according to an embodiment of the present disclosure.

Referring to FIG. 13A, a step of forming the first metal layer MTL1 on a substrate SUB may be performed. The substrate SUB may include a first area AA1 and a second area AA2. The substrate SUB may correspond to the base layer BL illustrated in FIG. 9. The first metal layer MTL1 may be disposed in the first area AA1.

Referring to FIG. 13B, a step of forming an insulating layer ILL on the first metal layer MTL1 and forming a preliminary inorganic layer P-IL on the insulating layer ILL may be performed. The insulating layer ILL may correspond to the fourth insulating layer 40 illustrated in FIG. 10.

Referring to FIG. 13C, a step of forming a preliminary photoresist layer P-PR on the preliminary inorganic layer P-IL may be performed. The preliminary photoresist layer P-PR may completely cover the preliminary inorganic layer P-IL.

Referring to FIG. 13D, a step of forming a photoresist layer PR by partially etching the preliminary photoresist layer P-PR may be performed. The preliminary inorganic layer P-IL may not be etched in the process of etching the preliminary photoresist layer P-PR. The photoresist layer PR may be formed on the second area AA2.

Referring to FIG. 13E, the preliminary inorganic layer P-IL that does not overlap the photoresist layer PR may be etched with the photoresist layer PR as a mask. The inorganic layer IL may be formed by etching the preliminary inorganic layer P-IL. For example, the inorganic layer IL may be formed by etching the preliminary inorganic layer P-IL through a dry etching process.

According to an embodiment of the present disclosure, the first depression portion DEP1 may be formed on the inorganic layer IL in the process in which the preliminary inorganic layer P-IL is etched. For example, since the photoresist layer PR has an increasing width in the third direction DR3, a portion of the inorganic layer IL disposed in the second area AA2 may be further etched due to the photoresist layer PR such that the first depression portion DEP1 may be formed on the inorganic layer IL. A residual inorganic layer R-IL may remain in the process in which the preliminary inorganic layer P-IL is etched. For example, the residual inorganic layer R-IL may be formed on the side surface of the photoresist layer PR.

Referring to FIG. 13F, a step of removing the photoresist layer PR disposed on the inorganic layer IL may be performed. The residual inorganic layer R-IL on the side surface of the photoresist layer PR may also be removed by removing the photoresist layer PR.

Referring to FIG. 13G, a step of forming the second metal layer MTL2 on the inorganic layer IL and the insulating layer ILL may be performed. The inorganic layer IL and the insulating layer ILL may provide a flat upper surface. Specifically, the second metal layer MTL2 may be disposed on the flat upper surface. According to an embodiment of the present disclosure, the second depression portion DEP2 may be formed on the second metal layer MTL2. The second depression portion DEP2 may be formed by the first depression portion DEP1 formed on the inorganic layer IL. Since the second metal layer MTL2 is formed on the flat upper surface, a possibility that the second metal layer MTL2 will be disconnected due to the step caused by the first metal layer MTL1 may be reduced.

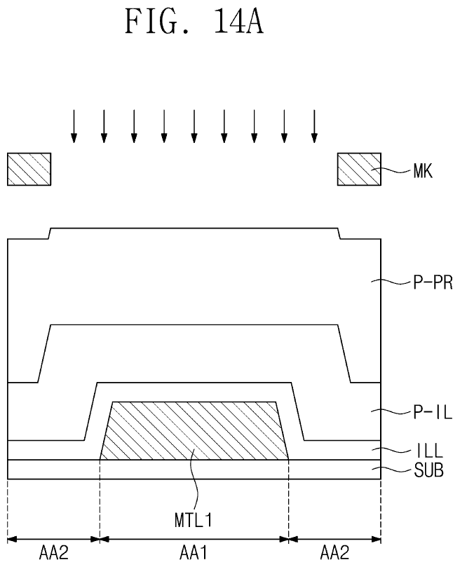

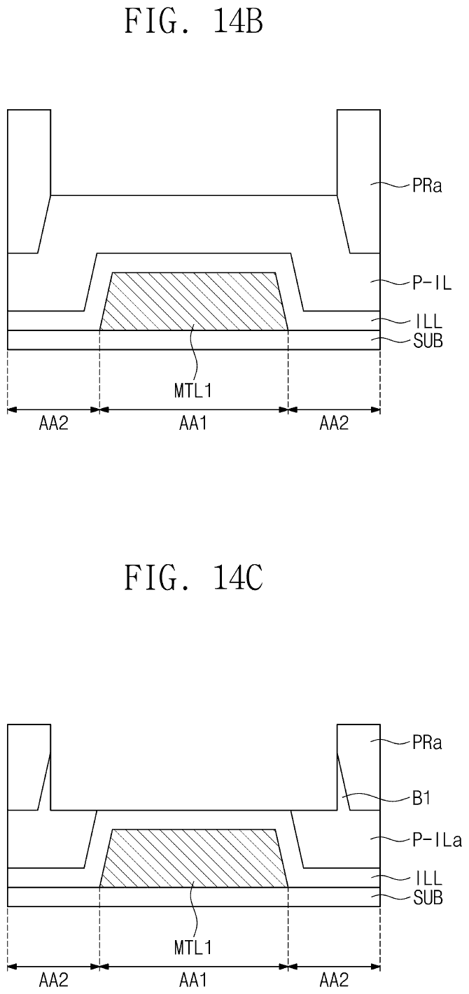

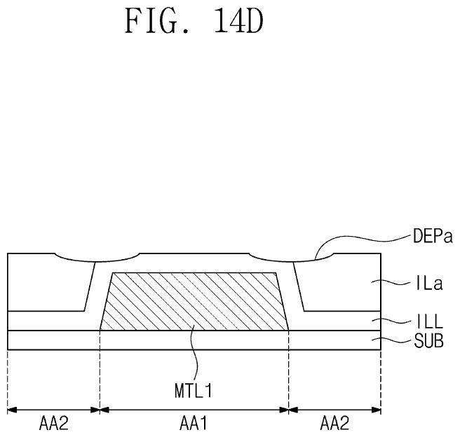

FIGS. 14A to 14D are process views illustrating a portion of a manufacturing process of the display device according to an embodiment of the present disclosure.

Referring to FIGS. 14A and 14B together, a process of etching the preliminary photoresist layer P-PR using a mask MK may be performed. A photoresist layer PRa may be formed by etching the preliminary photoresist layer P-PR. The preliminary inorganic layer P-IL may not be etched in the process of etching the preliminary photoresist layer P-PR.

Referring to FIG. 14C, a step of firstly etching the preliminary inorganic layer P-IL (refer to FIG. 14B) may be performed. In the first etching step, the preliminary inorganic layer P-IL and the photoresist layer PRa may be etched together. A preliminary inorganic layer P-ILa may include a first portion B1. The side surface of the first portion B1 may be parallel to the side surface of the photoresist layer PRa. In an embodiment, the etch rate of the preliminary inorganic layer P-IL and the etch rate of the photoresist layer PRa may be equal to each other.

Referring to FIGS. 14C and 14D together, a step of forming the inorganic layer ILa by secondly etching the preliminary inorganic layer P-ILa may be performed. For example, the second etching step may be performed by an isotropic dry etching process. Thus, a depression portion DEPa may be formed on the inorganic layer ILa. The depression portion DEPa may be formed by etching a portion of the inorganic layer ILa and a portion of the insulating layer ILL. Thereafter, although not illustrated, a step of forming the second metal layer MTL2 on the inorganic layer ILa and the insulating layer ILL as illustrated in FIG. 13G may be performed.

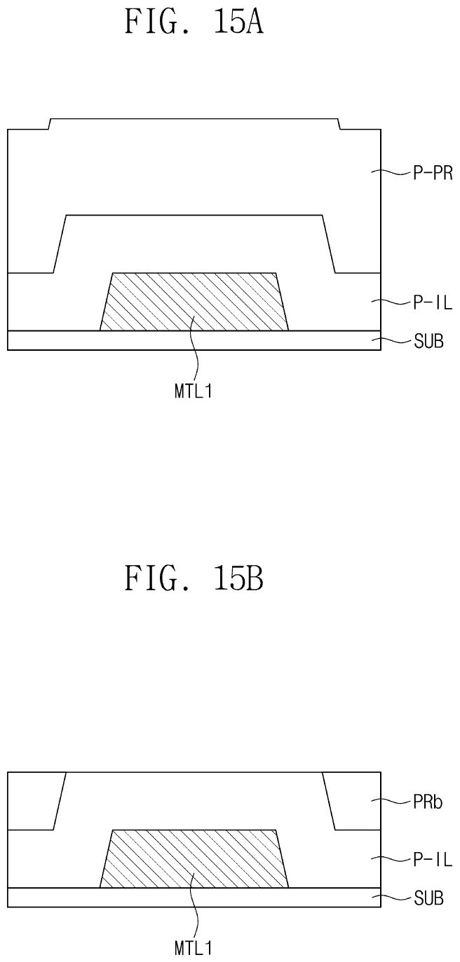

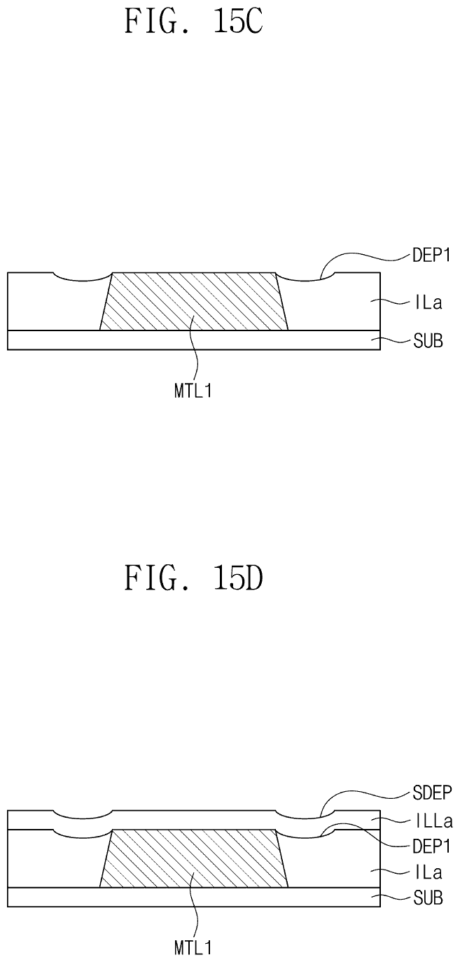

FIGS. 15A to 15D are process views illustrating a portion of a manufacturing process of the display device according to an embodiment of the present disclosure.

Referring to FIG. 15A, the preliminary inorganic layer P-IL may be directly formed on the first metal layer MTL1. The preliminary photoresist layer P-PR may be formed on the preliminary inorganic layer P-IL.

Referring to FIG. 15B, a step of forming a photoresist layer PRb by etching the preliminary photoresist layer P-PR may be performed. The preliminary inorganic layer P-IL may not be etched in the process of etching the preliminary photoresist layer P-PR.

Referring to FIGS. 15B and 15C, a step of etching the photoresist layer PRb and the preliminary inorganic layer P-IL may be performed. In an embodiment, the etch rate of the preliminary inorganic layer P-IL and the etch rate of the photoresist layer PRb may be equal to each other. Thus, in the process of etching the photoresist layer PRb and the preliminary inorganic layer P-IL, the photoresist layer PRb may all be removed, and the inorganic layer ILa may be formed. The first depression portion DEP1 may be formed on the inorganic layer ILa.

Referring to FIG. 15D, a step of forming the insulating layer ILLa on the first metal layer MTL1 and the inorganic layer ILa may be performed. The sub-depression portion SDEP may be formed on the insulating layer ILLa. The sub-depression portion SDEP may be formed by the first depression portion DEP1 formed on the inorganic layer ILa. Thereafter, although not illustrated, a step of forming the second metal layer MTL2 on the insulating layer ILLa as illustrated in FIG. 13G may be performed.

Referring to FIGS. 15A to 15D, since a process of adding a separate photo mask is omitted in the process of forming the inorganic layer ILa in accordance with one or more embodiments of the present disclosure, the display device DD (refer to FIG. 1) with a simplified manufacturing process may be provided.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” “may be removed,” “may be etched,” and the like include methods, processes, and techniques for disposing, forming, removing, and etching the element, and the like in accordance with example aspects described herein.

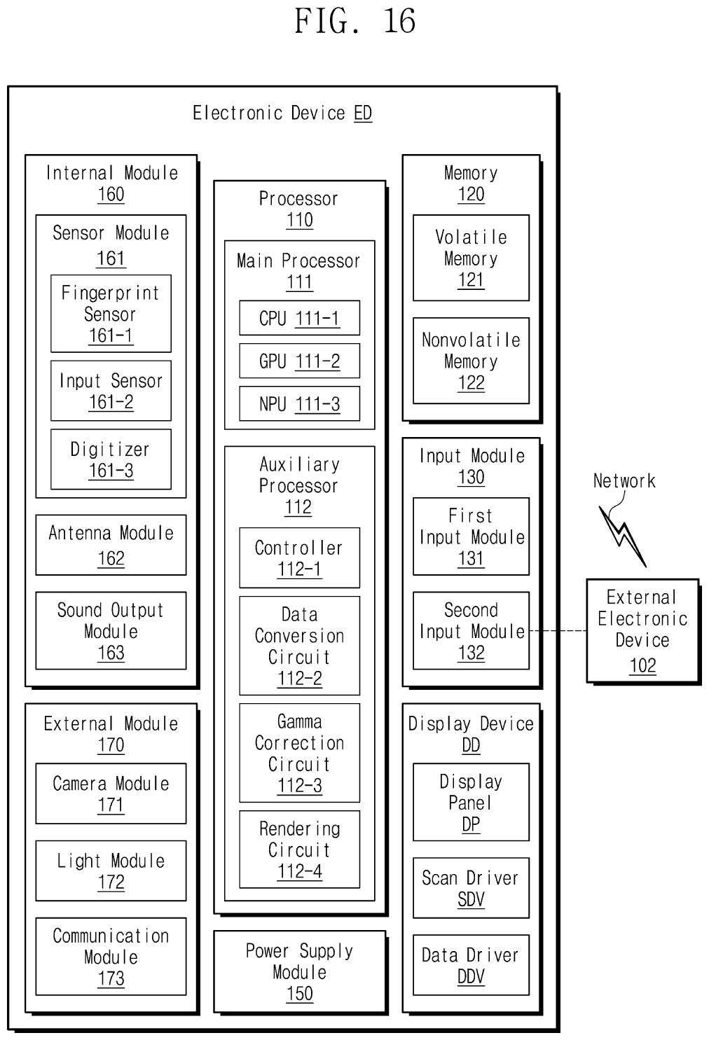

FIG. 16 is a block diagram of an electronic device including the display device according to an embodiment of the present disclosure.

Referring to FIG. 16, the electronic device ED may output a variety of information through the display device DD in an operating system. In an example in which a processor 110 executes an application stored in a memory 120, the display device DD may provide the user with application information through the display panel DP.

The processor 110 obtains an external input through an input module 130 or a sensor module 161 and executes an application corresponding to the external input. In an example in which the user selects a camera icon displayed on the display panel DP, the processor 110 obtains the user input through an input sensor 161-2 and activates a camera module 171. The processor 110 transfers image data corresponding to a captured image obtained through the camera module 171 to the display device DD. The display device DD may display an image corresponding to the captured image through the display panel DP.

In another example, when authentication for personal information is performed in the display device DD, a fingerprint sensor 161-1 obtains the input fingerprint information as input data. The processor 110 compares the input data obtained through the fingerprint sensor 161-1 and authentication data stored in the memory 120 and executes an application depending on a comparison result. The display device DD may display information executed depending on logic of the application, through the display panel DP.

In another example, when the user selects a music streaming icon displayed on the display device DD, the processor 110 obtains the user input through the input sensor 161-2 and activates a music streaming application stored in the memory 120. In an example in which a music play command is input to the music streaming application, the processor 110 activates a sound output module 163 and provides the user with sound information corresponding to the music play command.

The operation of the electronic device ED has been briefly described herein. Hereinafter, a configuration of the electronic device ED will be described in detail. Some of the components of the electronic device ED to be described herein may be integrally implemented with one component, and the one component may be divided into two or more components.

The electronic device ED may communicate with an external electronic device 102 over a network (e.g., a short-range wireless communication network or a long-range wireless communication network). According to an embodiment, the electronic device ED may include the processor 110, the memory 120, the input module 130, the display device DD, a power supply module 150, an internal module 160, and an external module 170. According to an embodiment, the electronic device ED may not include at least one of the above components or may further include one or more other components. According to an embodiment, some of the above components (e.g., the sensor module 161, an antenna module 162, or the sound output module 163) may be integrated into any other component (e.g., the display device DD).

The processor 110 may execute software to control at least one component (e.g., a hardware or software component) of the electronic device ED connected with the processor 110 and may perform various data processing or operations. According to an embodiment, as at least a part of the data processing or operations, the processor 110 may store a command or data received from any other component (e.g., the input module 130, the sensor module 161, or a communication module 173) in a volatile memory 121, may process the command or data stored in the volatile memory 121, and may store the processed data in a nonvolatile memory 122.

The processor 110 may include a main processor 111 and an auxiliary processor 112. The main processor 111 may include one or more of a central processing unit (CPU) 111-1 or an application processor (AP). The main processor 111 may further include one or more of a graphic processing unit (GPU) 111-2, a communication processor (CP), and an image signal processor (ISP).

The main processor 111 may further include a neural processing unit (NPU) 111-3. The neural processing unit 111-3 may be a processor specialized for processing of an artificial intelligence model, and the artificial intelligence model may be created through machine learning. The artificial intelligence model may include a plurality of artificial neural network layers.

The artificial neural network may include one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or a combination of two or more thereof, but embodiments of the present disclosure are not limited thereto.

In some aspects or alternatively, the artificial intelligence model may include a software structure in addition to a hardware structure. At least two of the above processing units and processors may be integrally implemented with one component (e.g., a single chip), or each of the above processing units and processors may be implemented with an independent component (e.g., a plurality of chips).

The auxiliary processor 112 may include a controller 112-1. The controller 112-1 may include an interface conversion circuit and a timing control circuit. The controller 112-1 receives an image signal from the main processor 111 and outputs image data obtained by converting the image signal to a data format suitable for the specification of an interface with the display device DD. The controller 112-1 may output various types of control signals supportive of driving the display device DD.

The auxiliary processor 112 may further include a data conversion circuit 112-2, a gamma correction circuit 112-3, a rendering circuit 112-4, and other circuitry. The data conversion circuit 112-2 may receive image data from the controller 112-1; the data conversion circuit 112-2 may compensate for the image data such that an image is displayed with a desired luminance depending on a characteristic of the electronic device ED or user settings or may convert the image data to reduce power consumption or to compensate for afterimages.

The gamma correction circuit 112-3 may convert the image data or the gamma reference voltage such that an image displayed on the electronic device ED has a desired gamma characteristic.

The rendering circuit 112-4 may receive the image data from the controller 112-1 and may render the image data in consideration of a pixel arrangement of the display panel DP applied to the electronic device ED.

At least one of the data conversion circuit 112-2, the gamma correction circuit 112-3, and the rendering circuit 112-4 may be integrated into any other component (e.g., the main processor 111 or the controller 112-1). At least one of the data conversion circuit 112-2, the gamma correction circuit 112-3, and the rendering circuit 112-4 may be integrated into the data driver DDV to be described herein.

The memory 120 may store various data used by at least one component (e.g., the processor 110 or the sensor module 161) of the electronic device ED and input data or output data for commands related thereto. The memory 120 may include at least one of the volatile memory 121 and the nonvolatile memory 122.

The input module 130 may receive a command or data to be used by a component (e.g., the processor 110, the sensor module 161, or the sound output module 163) of the electronic device ED from the outside of the electronic device ED (e.g., the user or the external electronic device 102).

The input module 130 may include a first input module 131 to which a command or data are input from the user and a second input module 132 to which a command or data are input from the external electronic device 102. The first input module 131 may include a microphone, a mouse, a keyboard, a key (e.g., a button), or a pen (e.g., a passive pen or an active pen).

The second input module 132 may support a specified protocol capable of connecting to the external electronic device 102 by wire or wirelessly. According to an embodiment, the second input module 132 may include a high definition multimedia interface (HDMI), a universal serial bus (USB) interface, a secure digital (SD) card interface, or an audio interface. The second input module 132 may include a connector capable of being physically connected with the external electronic device 102, for example, an HDMI connector, a USB connector, an SD card connector, or an audio connector (e.g., a headphone connector).

The display device DD visually provides information to the user. As described with reference to FIG. 4, the display device DD may include the display panel DP, the scan driver SDV, and the data driver DDV. The display device DD may further include a window, a chassis, and a bracket for protecting the display panel DP.

The display panel DP may include a liquid crystal display panel, an organic light emitting display panel, or an inorganic light emitting display panel, and the type of the display panel DP is not particularly limited. The display panel DP may be of a rigid type or may be of a flexible type capable of being rolled or folded. The display device DD may further include a supporter that supports the display panel DP, a bracket, or a heat radiating member.

The display device DD may further include a voltage generation circuit. The voltage generation circuit may output various types of voltages for driving the display panel DP.

The power supply module 150 supplies power to the components of the electronic device ED. The power supply module 150 may include a battery that charges a power supply voltage. The battery may include a primary cell that is not rechargeable, a secondary cell that is rechargeable, or a fuel cell. The power supply module 150 may include a power management integrated circuit (PMIC). The PMIC supplies power optimized for the display device DD and each of the modules. The power supply module 150 may include a wireless power transmission/reception member electrically connected with the battery. The wireless power transmission/reception member may include a plurality of antenna radiators that are in the form of a coil.

The electronic device ED may further include the internal module 160 and the external module 170. The internal module 160 may include the sensor module 161, the antenna module 162, and the sound output module 163. The external module 170 may include the camera module 171, a light module 172, and the communication module 173.

The sensor module 161 may sense an input by the user's body or an input by a pen of the first input module 131 and may generate an electrical signal or a data value corresponding to the input. The sensor module 161 may include at least one or more of the fingerprint sensor 161-1, the input sensor 161-2, and a digitizer 161-3.

The fingerprint sensor 161-1 may generate a data value corresponding to the user's fingerprint. The fingerprint sensor 161-1 may include one of an optical fingerprint sensor or a capacitive fingerprint sensor.

The input sensor 161-2 may generate a data value corresponding to coordinate information of the input by the user's body or the input by the pen. The input sensor 161-2 generates a capacitance change due to the input as a data value. The input sensor 161-2 may sense the input by the passive pen or may exchange data with the active pen.

The input sensor 161-2 may measure a biometric signal such as, for example, blood pressure, moisture, or body fat. In an example in which the user touches his/her body part to a sensor layer or a sensing panel and does not move during a given time period, the input sensor 161-2 may detect the biometric signal based on a change in an electric field caused by the body part and may output the information desired by the user to the display device DD.

The digitizer 161-3 may generate a data value corresponding to the coordinate information of the input by the pen. The digitizer 161-3 generates the amount of electromagnetic change by the input as a data value. The digitizer 161-3 may sense the input by the passive pen or may exchange data with the active pen.

At least one of the fingerprint sensor 161-1, the input sensor 161-2, and the digitizer 161-3 may be implemented with a sensor layer formed on the display panel DP through a continuous process. The fingerprint sensor 161-1, the input sensor 161-2, and the digitizer 161-3 may be disposed above/on the display panel DP, and at least one of the fingerprint sensor 161-1, the input sensor 161-2, and the digitizer 161-3, for example, the digitizer 161-3 may be disposed below/under the display panel DP.

At least two or more of the fingerprint sensor 161-1, the input sensor 161-2, and the digitizer 161-3 may be integrally formed with one sensing panel through the same process. In an example in which they are integrally formed with one sensing panel, the sensing panel may be disposed between the display panel DP and the window disposed above/on the display panel DP. According to one embodiment, the sensing panel may be disposed on the window, and the location of the sensing panel is not specifically limited.

At least one of the fingerprint sensor 161-1, the input sensor 161-2, and the digitizer 161-3 may be embedded in the display panel DP. That is, at least one of the fingerprint sensor 161-1, the input sensor 161-2, and the digitizer 161-3 may be simultaneously formed through a process of forming elements (e.g., a light emitting element and transistors) included in the display panel DP.

In some aspects, the sensor module 161 may generate an electrical signal or a data value corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas to transmit or receive the signal or power to or from an external source. According to an embodiment, through an antenna suitable for a communication method, the communication module 173 may transmit a signal to an external electronic device or may receive a signal from the external electronic device. An antenna pattern of the antenna module 162 may be integrated with one component (e.g., the display panel DP) of the display device DD or the input sensor 161-2.

The sound output module 163 that is a device for outputting a sound signal to the outside of the electronic device ED may include, for example, a speaker used for general purposes such as, for example, multimedia playback or recording playback and a receiver used exclusively for receiving calls. According to an embodiment, the receiver and the speaker may be either integrally or separately implemented. A sound output pattern of the sound output module 163 may be integrated with the display device DD.

The camera module 171 may photograph a still image and a moving image. According to one embodiment, the camera module 171 may include one or more lenses, an image sensor, or an image signal processor. The camera module 171 may further include an infrared camera capable of measuring the presence or absence of the user, the location of the user, and the line of sight of the user.

The light module 172 may provide a light. The light module 172 may include a light emitting diode or a xenon lamp. The light module 172 may operate in conjunction with the camera module 171 or may operate independently.

The communication module 173 may establish a wired or wireless communication channel between the electronic device ED and the external electronic device 102 and may support communication execution through the established communication channel. The communication module 173 may include one of a wireless communication module, such as, for example, a cellular communication module, a short-range wireless communication module, or a global navigation satellite system (GNSS) communication module, and a wired communication module, such as, for example, a local area network (LAN) communication module or a power line communication module or may include all thereof.

The communication module 173 may communicate with the external electronic device 102 over a short-range communication network such as, for example, Bluetooth, Wi-Fi direct, or infrared data association (IrDA) or a long-range communication network such as, for example, a cellular network, an Internet, or a computer network (e.g., a LAN or WAN). Various types of communication modules described herein may be implemented with one chip or with separate chips, respectively.

The input module 130, the sensor module 161, the camera module 171, or other components may be used to control the operation of the display device DD in conjunction with the processor 110.

The processor 110 outputs commands or data to the display device DD, the sound output module 163, the camera module 171, or the light module 172 based on the input data received from the input module 130. For example, the processor 110 may generate the image data corresponding to the input data applied through the mouse or the active pen and may output the image data to the display device DD; alternatively, the processor 110 may generate command data corresponding to the input data and may output the command data to the camera module 171 or the light module 172.

When input data are not received from the input module 130 during a given time period, the processor 110 may switch an operating mode of the electronic device ED to a low-power mode or a sleep mode such that the power consumption of the electronic device ED is reduced.

The processor 110 outputs commands or data to the display device DD, the sound output module 163, the camera module 171, or the light module 172 based on the sensing data received from the sensor module 161. For example, the processor 110 may compare authentication data obtained through the fingerprint sensor 161-1 with authentication data stored in the memory 120 and may then execute an application depending on a comparison result.

The processor 110 may execute a command based on the sensing data sensed by the input sensor 161-2 or the digitizer 161-3 or may output image data corresponding to the sensing data to the display device DD. In an example in which the sensor module 161 includes a temperature sensor, the processor 110 may receive temperature data associated with the measured temperature from the sensor module 161 and may further perform luminance correction on the image data based on the temperature data.

The processor 110 may receive measurement data about the presence or absence of the user, the location of the user, and the line of sight of the user from the camera module 171. The processor 110 may further perform the luminance correction on the image data based on the measurement data. For example, the processor 110 that determines the presence or absence of the user through the input from the camera module 171 may output, to the display device DD, image data whose luminance is corrected through the data conversion circuit 112-2 or the gamma correction circuit 112-3.

Some of the above components may be connected with each other through a communication scheme between peripheral devices, for example, a bus, a general purpose input/output (GPIO), a serial peripheral interface (SPI), a mobile industry processor interface (MIPI), or a ultra path interconnect (UPI) link and may exchange signals (e.g., commands or data). The processor 110 may communicate with the display device DD through a given interface. For example, one of the communication methods described herein may be used, and embodiments of the present disclosure are not limited thereto.

The electronic device ED according to various embodiments of the present disclosure may be implemented as various types of devices. The electronic device ED may include, for example, at least one of a portable communication device (e.g., a smart phone), a computer device, a portable multimedia device, a portable medical device, a camera, a wearable device, and home appliances. The electronic device ED according to an embodiment of the present disclosure is not limited to the above devices.

As described herein, in the display device of the present disclosure, the first metal layer disposed in the first area and the inorganic layer disposed in the second area may provide the flat upper surface. The second metal layer may be disposed on the flat upper surface provided by the first metal layer and the inorganic layer. Accordingly, the risk of disconnection by the first metal layer may be reduced. Thus, the display device with reliability may be provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a base layer;
a first metal layer disposed on the base layer and disposed in a first area;
an inorganic layer disposed on the base layer and disposed in a second area; and
a second metal layer disposed on the first metal layer and the inorganic layer,
wherein a depression portion adjacent to the first metal layer and formed in a thickness direction of the inorganic layer is defined in the inorganic layer.

2. The display device of claim 1, further comprising an insulating layer disposed on the first metal layer.

3. The display device of claim 2, wherein:
the insulating layer is disposed between the base layer and the inorganic layer, and
the insulating layer completely covers the first metal layer.

4. The display device of claim 3, wherein the insulating layer comprises:
a first upper surface which overlaps the inorganic layer; and
a second upper surface which does not overlap the inorganic layer,
wherein the second upper surface and the second metal layer are contacting each other.

5. The display device of claim 2, wherein the insulating layer is disposed on the inorganic layer and the first metal layer.

6. The display device of claim 5, wherein the second metal layer is directly disposed on the insulating layer.

7. The display device of claim 5, wherein a sub-depression portion corresponding to the depression portion is defined in the insulating layer.

8. The display device of claim 1, wherein a thickness of the inorganic layer is equal to a thickness of the first metal layer.

9. The display device of claim 1, further comprising:
a first transistor disposed on the base layer; and
a second transistor disposed over at least a portion of the first transistor.

10. The display device of claim 9, wherein:
the first transistor comprises a first semiconductor layer and a first gate electrode disposed over the first semiconductor layer, and
the second transistor comprises a second semiconductor layer and a second gate electrode disposed under the second semiconductor layer.

11. The display device of claim 10, wherein:
the second gate electrode corresponds to the first metal layer, and
the second semiconductor layer corresponds to the second metal layer.

12. The display device of claim 10, wherein the first semiconductor layer and the second semiconductor layer overlap each other when viewed from above a plane.

13. An electronic device comprising:
a camera module; and
a display device which displays an image corresponding to a captured image obtained through the camera module,
wherein the display device comprises:
a base layer;
a first metal layer disposed on the base layer and disposed in a first area;
an inorganic layer disposed on the base layer and disposed in a second area; and
a second metal layer disposed on the first metal layer and the inorganic layer,
wherein a depression portion adjacent to the first metal layer and formed in a thickness direction of the inorganic layer is defined in the inorganic layer.

14. A method for manufacturing a display device, the method comprising:
a step of forming a base layer comprising a first area and a second area which does not overlap the first area;
a step of forming, on the base layer, a first metal layer which overlaps the first area;
a step of forming a preliminary inorganic layer on the base layer and the first metal layer;
a step of forming an inorganic layer which overlaps the second area, by etching the preliminary inorganic layer; and
a step of forming a second metal layer on the first metal layer and the inorganic layer,
wherein a depression portion adjacent to the first metal layer and formed in a thickness direction of the inorganic layer is defined in the inorganic layer in the step of forming an inorganic layer.

15. The method of claim 14, wherein the step of forming the inorganic layer comprises:
a step of forming a preliminary photoresist layer on the preliminary inorganic layer; and
a step of forming a photoresist layer which overlaps the second area, by etching the preliminary photoresist layer.

16. The method of claim 15, wherein the step of forming the inorganic layer further comprises a step of removing the photoresist layer after etching the preliminary inorganic layer.

17. The method of claim 15, wherein an etch rate of the photoresist layer and an etch rate of the preliminary inorganic layer are equal to each other.

18. The method of claim 14, further comprising:
a step of forming an insulating layer on the first metal layer before the step of forming the preliminary inorganic layer.

19. The method of claim 18, wherein the second metal layer is directly disposed on the inorganic layer and the insulating layer.

20. The method of claim 14, further comprising:
a step of forming an insulating layer on the inorganic layer and the first metal layer, between the step of forming the inorganic layer and the step of forming the second metal layer, and wherein the second metal layer is directly disposed on the insulating layer.
